(19) United States
(12) Patent Application Publication
(10) Pub. No.: US 2004/0266208 A1
(43) Pub. Date: Dec. 30, 2004

(54) Method for preventing particle-based contamination of substrates and structure therefor

(76) Inventor: Yasuto Karasawa, Tokyo (JP)

Correspondence Address: OSHA & MAY L.L.P., 1221 MCKINNEY STREET, HOUSTON, TX, 77010, US

(21) Appl. No.: 10/606,328

(22) Filed: Jun. 25, 2003

(51) Int. Cl. H01L 21/302; H01L 21/461

(52) U.S. Cl. 438/737

(57) ABSTRACT

A method for preventing a substrate W from being contaminated by particles are provided, where the substrate is held horizontally, by means of holding means, in an environment having a specified cleanliness. The method comprises the step of flowing clean gas, by means of gas flowing means along the top surface of the substrate at a specific relative horizontal speed with respect to the top surface of the substrate, such that a laminar boundary layer, a transition layer, and/or turbulent boundary layer, of the clean gas are formed all over an entire area of the top surface of the substrate. In this method, the gas within the laminar boundary layer, a transition layer, and/or turbulent boundary layer, of clean gas may be considered as a viscous fluid. Thus, even if particles are existing and floating in the environment, where the substrate is disposed, and falling towards the substrate, the particles falling onto the substrate are blocked with the viscous fluid layer existing over the substrate. In other words, this viscous fluid layer functions as a protective coating or layer, thereby preventing the substrate from being contaminated by the particles.

### BACKGROUND OF THE INVENTION

1. Field of the Invention

The present invention relates to a technology for preventing a substrate, such as a semiconductor wafer and a glass substrate, from being contaminated by dirt and/or other minute fragments (hereinafter collectively called as particles).

2. Related Background Art

Micro-devices, such as semiconductor devices and LCD (liquid crystal display) panels, are recently demonstrating an ever-growing tendency towards finer structures and higher degrees of integration. Along with this tendency, contamination caused by particles, or particle-based contamination, of the surface of substrates for those devices is producing a serious problem likely to cause various defects. Typical countermeasures against this problem so far taken have been to create an extremely clean space for handling a substrate therein, such as transferring and stocking.

Under the existing circumstances, however, there is a limit to increasing the space cleanliness, whereby it is substantially impossible to create a space with particles completely removed.

Therefore, it may be caused that, in case a substrate is being stocked as held horizontally in a clean space for substrate stocking, particles existing and floating in the space have been deposited on the top surface of the substrate before long no matter how little the amount of the particles is.

Furthermore, as for single-substrate based conveying of substrates, methods of such conveying have so far been proposed where the conveying is performed through clean tunnels. In this conveying environment, abrasion in the mechanical parts of the conveying equipment may inevitably cause particles to generate, which may enter into the clean tunnels and thereby are likely to cause a higher possibility of particle-based contamination of the substrates.

Thus, an object of the present invention is to provide a method and structure for preventing a substrate from being contaminated by particles in the course of substrate handling, such as conveying, transferring and stocking.

### SUMMARY OF THE INVENTION

In order to accomplish the object described above, in one aspect of the present invention, a method for preventing a substrate from being contaminated by particles is provided, where the substrate is disposed horizontally in an environment having a specified cleanliness. The method according to the present invention comprises: the step of flowing clean gas along the top surface of the substrate at a specific relative horizontal speed with respect to the top surface of the substrate, such that a protective coating of the clean gas for protecting the substrate from particles is formed all over an entire area of the top surface of the substrate. The protective coating includes a laminar boundary layer, a transition layer, and/or a turbulent boundary layer.

By arranging a method for preventing particle-based contamination of a substrate, as described above, the gas within the protective coating, i.e. laminar boundary layer, a transition layer, and/or a turbulent boundary layer, of clean gas so formed over the top surface of the substrate, maybe considered as a viscous fluid. Thus, even if particles are existing and floating in the environment, where the substrate is disposed, and falling towards the substrate, the particles falling onto the substrate are blocked with the viscous fluid layer existing over the substrate. In other words, this viscous fluid layer functions as a protective coating, thereby preventing the substrate from being contaminated by the particles. It is noted that a typical clean gas used for the purpose may be air adapted to have the specific cleanliness.

In another aspect of the present invention, a structure for preventing a substrate from being contaminated by particles is also provided. The structure for preventing particle-based contamination of a substrate comprises: a housing having the inside thereof kept at a specified cleanliness; a holding means for holding the substrate horizontally inside the housing; and a gas flowing means for flowing clean gas along the top surface of the substrate at a specific relative horizontal speed with respect to the top surface of the substrate, such that a protective coating of the clean gas is formed all over an entire area of the top surface of the substrate. The protective coating includes a laminar boundary layer, a transition layer, and/or a turbulent boundary layer.

The holding means may have a function of moving the substrate within the housing. In this case, the configuration of the structure according to the present invention, as described above, is applicable to a substrate conveyance system. Specifically, such function of transferring a substrate held by the holding means, is enabled by arranging the inside of the housing as a substrate conveying path and adapting the holding means to be capable of moving, besides holding, the substrate within the housing.

In this arrangement, the holding means is adapted to be capable of moving the substrate. Then, the horizontal speed of the clean gas flowing along the top surface of the substrate may be adjusted to such a specific relative horizontal speed with respect to the top surface of the substrate that enables a laminar boundary layer, a transition layer, and/or turbulent boundary layer, of the clean gas to form all over an entire area of the top surface of the substrate.

Where the holding means is adapted to be not capable of moving the substrate within the housing, the structure of the present invention is exclusively for use in substrate holding means, such as for substrate stocking.

Preferably, the gas flowing means includes: a fan for circulating gas within the housing; and a filter disposed in a path of the gas circulation, for cleaning the gas to a clean gas having a specified cleanliness.

The gas circulation within the housing enables to create a cleaner environment very effectively in terms of efficiency and cost of the operation.

Since air, as the clean gas, may be used in a dry condition, particles and a substrate are likely to be charged with static electricity caused by friction within airflow, which might cause effects adverse to the substrate. To solve the problem, preferably, an ion supply means may be disposed for supplying the inside of the housing with ion for neutralizing such static electricity occurring in particles contained in the clean gas. This arrangement may enable to prevent particles from adhering to the substrate due to the static electricity.

These and other features and advantages of the present invention may become more apparent by referring to the following detailed description and accompanying drawings briefly described below.

### BRIEF DESCRIPTION OF THE DRAWINGS

In the course of the following detailed description, reference will be made to the attached drawing in which:

FIG. 1 is a schematic, longitudinal sectional view of a substrate conveyance system with a particle-based contamination preventive structure, according to the present invention, applied thereto;

FIG. 2 is a vertical sectional view taken along the arrow lines II-II in FIG. 1;

FIG. 3 is a partial longitudinal sectional view of one of two front ends of an end-effector of the substrate transfer robot shown in FIGS. 1 and 2;

FIG. 4 is a schematic diagram showing the behavior of airflow in conjunction with a semiconductor wafer to illustrate a method of preventing particle-based contamination, according to the present invention; and

FIG. 5 is a schematic, longitudinal sectional view of a FOUP (Front Opening Unified Pod) system with a particle-based contamination preventive structure applied thereto, according to the present invention.

### DESCRIPTION OF THE PREFERRED EMBODIMENTS

Referring now to the drawings attached hereto, the present invention is described more in detail, according to preferred illustrative embodiments thereof. In the following description, like reference characters designate like or corresponding parts throughout the views.

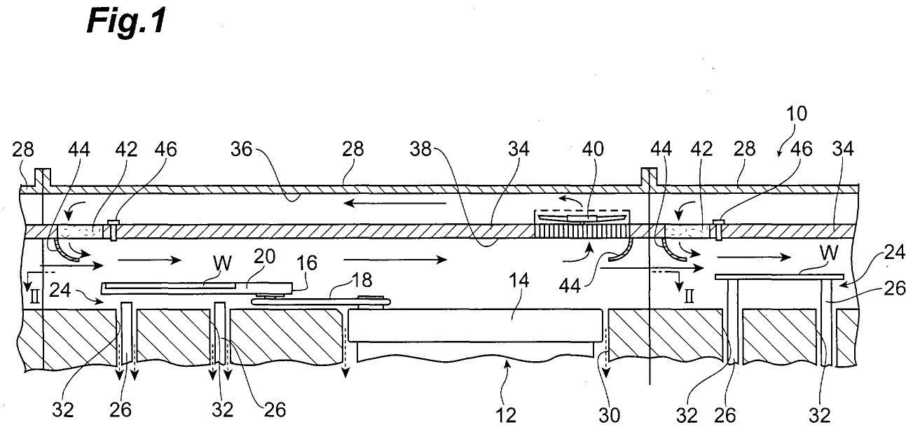

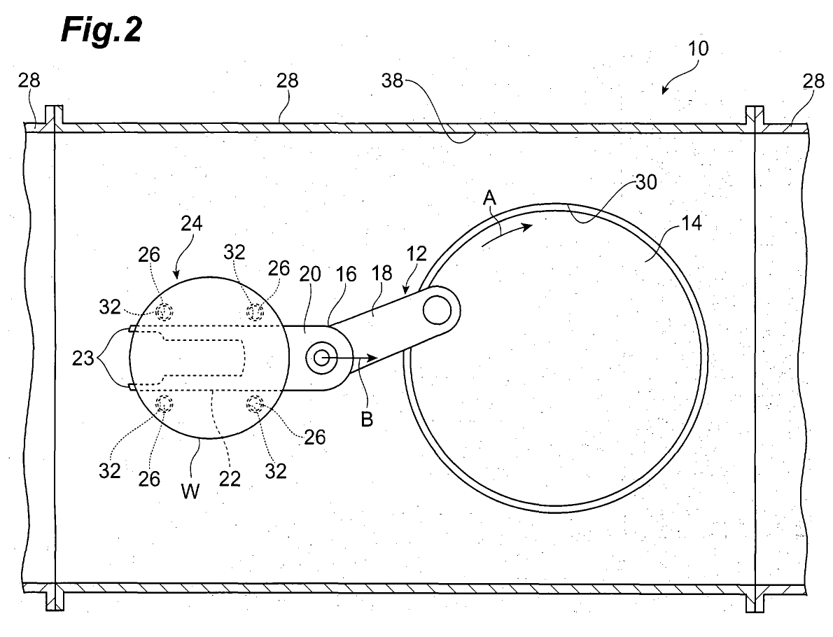

FIGS. 1 and 2 illustrate a preferred embodiment of the structure for preventing particle-based contamination of a substrate, according to the present invention, as applied to a substrate conveyance system 10. The substrate conveyance system 10, as shown, is adapted to transfer a semiconductor wafer W, as the substrate, in one direction, which is the direction from left to right in FIGS. 1 and 2. The substrate conveyance system 10 has a substrate transfer robot 12 as the principal component.

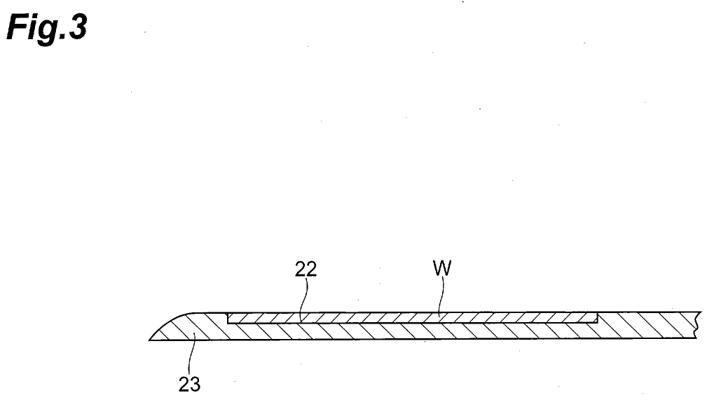

The substrate transfer robot 12 is basically a well-known robot of arm-type, and includes a rotatable, disk-shaped base 14, and an arm assembly 16 rotatably and eccentrically attached to the base 14. The arm assembly 16 has an arm 18, with one end thereof attached on the base 14, and a work-handling arm, or end-effector, 20. The end-effector 20 has one end thereof rotatably attached to the other end of the arm 18. The end-effector 20 has the front end on the other end thereof. The front end of the end-effector 20 is equipped with a holding means for holding a semiconductor wafer W. While various types are possible for the holding means, the holding means used in this embodiment is a circular-shaped recess formed on the top surface of the end-effector 20 such that the wafer W fits the recess, as seen in FIG. 3. This recess has a depth equal to the thickness of the semiconductor wafer W, and has the internal circumferential wall thereof formed in the same contour as the external circumferential contour of the semiconductor wafer W such that the semiconductor wafer w is prevented from erroneous horizontal positioning. The front end 23 of the end-effector 20 has a two-pointed fork shape, as seen in FIG. 2. The top surface of the front end 23 is streamlined longitudinally in a vertical plane as also seen in FIG. 3. This streamlined shape is adopted to flow the gas, or air, as smoothly as possible along the top surface of the semiconductor wafer W.

Inside the base 14, arm 18 and end-effector 20, there are linking and/or driving mechanisms (not shown) disposed, which enable the semiconductor wafer W being held by the recess 22 of the end-effector 20 to proceed linearly along an arrow B when the base 14 is rotated along an arrow A, as shown in FIG. 2. An intermittent transfer of a substrate in a greater distance may be made possible by linearly arranging a plurality of such substrate transfer robots 12, and a plurality of the housings 28 connected side by side, respectively.

In this embodiment, the substrate transfer robot 12, described above, is not adapted to directly transfer a substrate to another substrate transfer robot adjacent thereto. Therefore, the substrate conveyance system 10 in this embodiment has a substrate transfer stand 24 disposed between a pair of substrate transfer robots 12 adjacent to each other. The substrate transfer stand 24 is equipped with a plurality, preferably four, of lift pins 26, as holding means, adapted to be vertically movable by means of driving mechanism (not shown). A semiconductor wafer W is adapted to be held on the bottom surface thereof by means of the lift pins 26, when placed on the substrate transfer stand 24. With this arrangement, the semiconductor wafer W is enabled to be transferred between the substrate transfer stand 24 and the substrate transfer robot 12. This transferring action is implemented by the up- and downward motions of the lift pins 26 of the substrate transfer stand 24, together with the insertion and withdrawal motions, in between the lift pins 26, of the end-effector 20 of the substrate transfer robots 12. The lift pins 26 are adapted to contact only the bottom surface of the semiconductor wafer W, similarly to the end-effector 20 in this embodiment.

One substrate transfer robot 12 and one substrate transfer stand 24 constitute a pair of transfer equipment. Each pair of the substrate transfer robot 12 and the substrate transfer stand 24 are enclosed within a tubular or tunnel shaped housing 28. The housing 28 extends in the same direction as the transfer direction of the semiconductor wafer W. Both ends of the housing 28 are open. The substrate transfer robots 12 of the pair of transfer equipment, described above, is located near to one open end of the housing 28 on the downstream side along the transfer direction, or the right side in FIG. 2. The substrate transfer stand 24 of the pair is located near to the other open end of the housing 28 on the upstream side along the transfer direction, or the left side in FIG. 2. The base 14 of the substrate transfer robot 12 is located within an opening 30 formed in the inside bottom surface of the housing 28, with the top surface thereof kept at the same level as the inside bottom surface of the housing 28. This arrangement of the base 14 is also devised to lessen obstacles within the housing 28 for preventing vortexes and turbulence from occurring in the airflow on and over the top surface of the semiconductor wafer W. The lift pins 26 of the substrate transfer stand 24 are disposed through holes 32 formed in the inside bottom surface of the housing 28.

It is noted that gaps are respectively formed between the base 14 of the substrate transfer robot 12 and the opening 30 of the housing 28, and between the lift pins 26 of the substrate transfer stand 24 and the holes 32 of the housing 28. This results in preventing abrasion of those engaging members due to mechanical contact there between from occurring. Furthermore, as shown by dotted arrow lines in FIG. 1, air within the housing 28 is adapted to be slowly drawn out downwards through those gaps. This is useful for preventing or restraining particles, that may generate due to mechanical abrasion in the substrate transfer robot 12 and the substrate transfer stand 24 themselves, from remaining in or entering into the housing 28.

The inside space of the housing 28 is divided into the upper space 36 and the lower space 38 by means of a division plate 34. The division plate 34 has an opening located near to one end thereof on the downstream side along the transfer direction, or the right side in FIG. 1. The opening in the right-side end of the division plate 34 has a fan 40 installed therein for sucking air from the lower space 38 of the housing 28 and flowing the sucked air into the upper space 36 of the housing 28. The division plate 34 also has another opening located near to the other end thereof on the upstream side along the transfer direction, or the left side in FIG. 1. The opening in the left-side end of the division plate 34 has a filter 42, such as a HEPA (High Efficiency Particulate Air) filter and an ULPA (Ultra Low Penetration Air) filter, installed therein.

With this arrangement, when the fan 40 is activated, air circulates as shown by solid arrow lines in FIG. 1, from the lower space 38 through the fan 40 into the upper space 36. The air then further flows through the filter 42. After filtered through the filter 42, the air, now clean air, as clean gas, flows from the upstream open end of the housing 28 on the left side in FIG. 1 towards the downstream open end of the housing 28 on the left side in FIG. 1. This arrangement enables to maintain the lower space 38 of the housing 28 in the specified cleanliness. The openings for the fan 40 and the filter 42 on both ends of the division plate 34 are respectively equipped with a baffle plate 44 to divert the direction of the airflow to horizontal after the filter 42 and to vertical before the fan 40.

In addition, the division plate 34 of the housing 28 also has an ion supply nozzle 46, as ion supply means, installed near to and on the downstream side of the filter 42. This ion supply nozzle 46 is installed to neutralize static electricity that may occur in particles contained in the clean gas due to friction within the airflow. This arrangement may enable to prevent particles from being charged with the static electricity and thereby adhering to the substrate due to the static electricity.

A plurality of the housings 28, arranged as described above, may be linearly assembled together by connecting each open end thereof to the opposite open end of another housing 28 adjacent thereto, to form a single clean tunnel of a greater length as a substrate-conveying path. Then, a semiconductor wafer conveyance system 10 may be implemented along a clean tunnel by arranging the clean tunnel as described above, and by properly controlling each substrate transfer robot 12 and each substrate transfer stand 24 installed within each housing 28 constituting the clean tunnel.

Now, an illustrative description will be made for the operation of the method for preventing particle-based contamination of a substrate, according to the present invention, as applied to a substrate conveyance system 10, arranged as described above, including a plurality of housings 28, substrate transfer robots 12 and substrate transfer stands 24.

First, a case is considered where the semiconductor wafer W is held stationary on a substrate transfer stand 24 in a housing 28. When air is circulated within each housing 28 by activating the fan 40, clean air flows substantially horizontally in the same direction as that of the substrate transport within the lower space 38 of each housing 28. Since a plurality of housings 28 are connected, with the inside of the plurality of housings 28 communicating with each other, the clean air flows horizontally throughout an entire number of housings 28. The flow rate, or speed, of the clean air may be preferably made 100 to 300 mm/sec for a satisfactory operation.

Under the condition that such slow airflow is occurring, and assuming a semiconductor wafer W of 300-mm diameter is held on lift pins 26, as shown in a housing 28 on the right side of FIG. 1, the Reynolds number of airflow on the leading edge (the front end facing the airflow) of the semiconductor wafer W may be at a level of tens since the dynamic viscosity of air is 0.15 cm²/sec under an ambient temperature of 20 degrees Centigrade. The Reynolds number of airflow on the trailing edge of the semiconductor wafer W (a point downstream by 300 mm from the leading edge) may be around 6,000 even with the flow rate of 300 mm/sec.

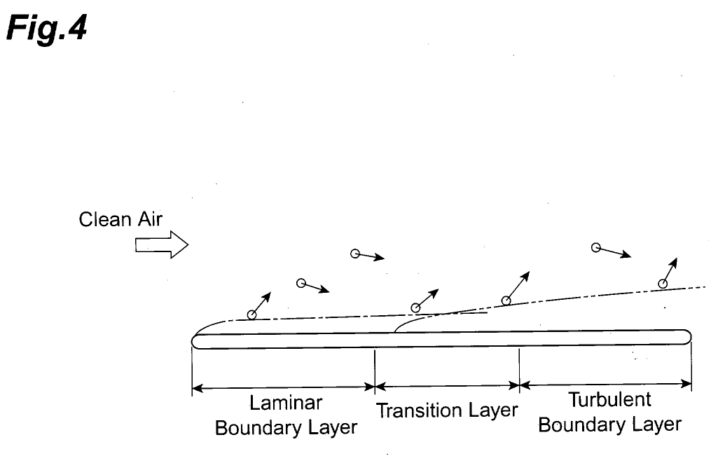

Within this range of values, layers formed on the top surface of the semiconductor wafer W, are observed to include, in the order from the leading edge on the left side to the trailing edge on the right side, as shown in FIG. 4, a laminar boundary layer of 20 to 30 mm in the horizontal length (one-dotted chain line in FIG. 4), a transition layer and a turbulent boundary layer (two-dotted chain line in FIG. 4). Those layers all maintain a nature of viscous fluid with respect to minute particles P, and act as a protective coating for protecting the wafer W from particles P. Furthermore, semiconductor wafers W currently being commercialized have the external circumferential edge thereof formed in a substantially semi-circular shape along the radial cross-section thereof, and, besides, the airflow is slow in this embodiment. Therefore, vortexes are not likely to generate even when the airflow is brought in contact with the leading edge of such semiconductor wafer W. In addition, since the front end 23 of the end-effector 20 is formed streamlined as shown in FIG. 3, turbulence, such as vortexes, is restrained from occurring.

Therefore, even when minute particles P are existing and floating above the semiconductor wafer W, and further falling down while somewhat being drifted away by means of the airflow, a laminar boundary layer, a transition layer and/or a turbulent boundary layer, are formed. All the layers are viscous fluids with respect to particles P.

This formation of the viscous layers prevents the particles P from increasing the falling speed thereof. Subsequently, the particles P are caused to drift towards downstream farther than the semiconductor wafer W by accompanying the mainstream of the airflow (airflow high above the laminar boundary layer, a transition layer, and/or a turbulent boundary layer. The floating particles P so drifted are sucked in by the fan 40, together with the circulated air, and then are flowed through the upper space 36 of the housing 28, and removed from the air when the air passes through the filter 42.

Here, an observation will be made assuming a case where quartz particles are floating in the housing 28 with a diameter of 1.0 μm larger than standard particles with a diameter of 0.1 μm as specified in JIS (Japanese Industrial Standards) standards for cleanliness in Japan. Since each single particle observed weighs as extremely light as 1.3 μg (picograms), these particles are securely blocked by the laminar boundary layer, transition layer, and/or turbulent boundary layer, all being viscous fluid, and not likely to reach and pollute the top surface of the semiconductor wafer W.

Back to the present embodiment, the air flowing within the lower space 38 of the housing 28 is of course extremely clean since particles are removed by means of the filter 42, such as a HEPA or ULPA filter. In addition, particles originating in the substrate transfer robot 12 and the substrate transfer stand 24 themselves, are prevented from remaining in or entering into inside of the housing 28. This is because the air is drawn out downwards through gaps formed between the base 14 of the substrate transfer robot 12 and the opening 30 of the housing 28, and between the lift pins 26 of the substrate transfer stand 24 and the holes 32 of the housing 28. Thus, in this embodiment, particles with a diameter as large as 1 μm extremely hardly exist within the housing 28.

Next, another case is considered where the semiconductor wafer W is moved or transported in the housings 28. For transporting the semiconductor wafer W, using the substrate transfer robot 12, it is necessary that the semiconductor wafer W, being held on the lift pins 26 of the substrate transfer stand 24, is transferred onto the end-effector 20 of the substrate transfer robot 12. For the purpose, specifically, the substrate transfer stand 24 and the substrate transfer robot 12 are controlled such that the lift pins 26 are moved upwards to a level higher than the end-effector 20, and the recess 22 of the end-effector 20 is positioned below the semiconductor wafer W being held on the lift pins 26. The lift pins 26 are thereafter moved downwards to cause the semiconductor wafer W transferred onto, and held in, the recess 22 of the end-effector 20.

Then, the substrate transfer robot 12 is controlled such that the base 14 is rotated in the direction of an arrow A, providing a crank action, and the arm assembly 16 is simultaneously given link-bending actions. This enables the recess 22 of the end-effector 20, and in turn the semiconductor wafer W, to proceed, or be transferred linearly along the arrow B, or rightwards in the longitudinal direction of the end-effector, as seen in FIG. 2. The transfer of the semiconductor wafer W may be preferably performed at a maximum speed of 100 to 200 mm/sec for satisfactory operations. The maximum transfer speed may be set so that the relative horizontal speed of the airflow with respect to the semiconductor wafer W falls within a range of 100 to 200 mm/sec.

When the semiconductor wafer W is being moved, or transferred, and the relative horizontal speed of the airflow with respect to the semiconductor wafer W is within a range of 100 to 200 mm/sec, the behavior of the clean air on the top surface of the semiconductor wafer W is the same as of the semiconductor wafer W standing stationary. Namely, a laminar boundary layer, a transition layer, and a turbulent boundary layer of the air are formed on the top surface of the semiconductor wafer W. This results in particles being prevented from adhering to the top surface of the semiconductor wafer W.

In this operation, static electricity-caused by the air flowing also may be neutralized by ion provided from the ion supply nozzle 46, whereby the particles are prevented from adhering to the semiconductor wafer W due to the static electricity.

In the semiconductor manufacturing processes, while single-substrate based conveyance system concepts of in-line type have been so far proposed, those concepts have never been actually implemented due to contamination by dusts, or particles, occurring in various mechanisms for transferring and transporting semiconductor wafers W in the conveyance system. However, such single-substrate based conveyance of in-line type is enabled to materialize by arranging a substrate conveyance system 10, according to the present invention, as described above, since the arrangement may prevent or greatly restrain those particles from adhering to semiconductor wafers W. Such materialization, particularly of the single-substrate based conveyance, is greatly useful for solving the batch type conveyance having difficulty in handling semiconductor wafers W with diameters getting far greater than before. This may result in a remarkable contribution to improvement of semiconductor wafer productivity.

In the embodiment described above, a substrate transfer robot 12 is used, as holding means capable of moving a substrate, to transfer the semiconductor wafer W. It should be easily understood however that the transfer means, as the holding means capable of moving a substrate, is not limited to a robot.

Moreover, the shape and holding position of the holding means for holding the semiconductor wafer W are not limited to those used in the embodiment described above, as far as a laminar boundary layer, a transition layer, and/or a turbulent boundary layer are formed on the top surface of the semiconductor wafer W.

Furthermore, the present embodiment has been described above by involving a case (i) where a laminar boundary layer, a transition layer, and a turbulent boundary layer, of the air are all formed on the top surface of the semiconductor wafer W as a protective coating. Depending on factors, such as the airflow speeds and the diameters of the semiconductor wafer W, however, the airflow may be controlled so that either one of four additional combinations of air layers is formed on the top surface of the semiconductor wafer W. Those additional combinations of air layers are also useful for preventing particles in the airflow from reaching the top surface of the semiconductor wafer, as envisioned by the present invention. Such four additional useful combinations of air layers formed on the top surface of the semiconductor wafer W include combinations of (ii) only a laminar boundary layer, (iii) only a laminar boundary layer and a transition layer, (iv) only a transition layer and a turbulent boundary layer, or (v) only a turbulent boundary layer. All the five cases or combinations of air layer formation described above are intended to be included in the claims of the present invention. For the purpose, the expression of “a laminar boundary layer, a transition layer, and/or turbulent boundary layer” is used in this specification and claims to mean that either and all of the five combinations of air flow layers are included within the scope of claims.

In addition, in describing the present embodiment above, some illustrative values of airflow speeds have been shown. However, any airflow speed may be used as far as a laminar boundary layer, a transition layer, and/or a turbulent boundary layer are formed on the top surface of the semiconductor wafer W as a protective coating. Such that, the airflow speed may be changed to certain values as required, according to factors, such as the internal structure of the housing, the substrate moving speed of the holding means, kinds of gases uses as the clean gas, and the ambient temperature.

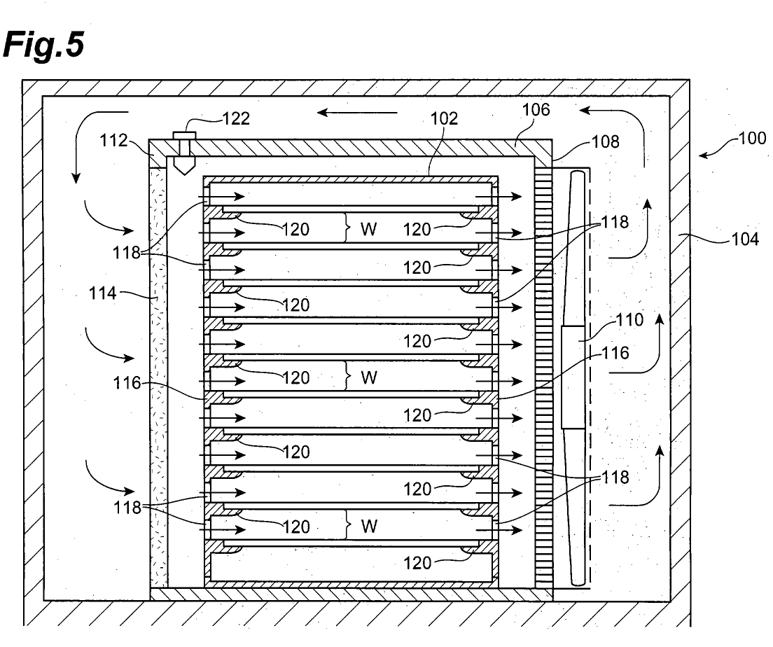

FIG. 5 shows a second embodiment of the present invention applied to a FOUP (Front opening Unified Pod) system 100. FOUPs are currently being used in the conventional batch type semiconductor manufacturing processes for handling, transferring and stocking semiconductor wafers. A tendency is foreseen that FOUPs are also adopted in the semiconductor wafer conveyance systems in conjunction with semiconductor manufacturing processes. A FOUP is a wafer cassette of an open front-end type. The FOUP is enclosed within a housing having a small closed space therein, where the front end of the housing is opened to put semiconductor wafers in and out. The FOUP is considered being proof against contamination caused by particles, since it is placed within the small space where a high cleanliness can be achieved. However, even a small space is difficult to completely get rid of particles.

As shown in FIG. 5 illustrating the second embodiment of the present invention, the FOUP system 100 has a housing 104 for accommodating a FOUP 102. The FOUP 102 is implemented as holding means for holding semiconductor wafers W. The housing 104 has a sub-housing 106 disposed therein, whereby the inside of the housing 104 is divided into double spaces. The FOUP 102 is enclosed within the sub-housing 106. The sub-housing 106 has two sidewalls 108, 112. One 108 of the sidewalls is equipped with a fan 110 for sucking air from the inside space of the sub-housing 106. The other sidewall 112 is equipped with a filter 114, such as a HEPA filter or an ULPA filter. It is arranged such that, when the fan 110 is activated, air flows as shown with arrows in FIG. 5, and clean air filtered through the fan 114 communicates horizontally to form a space having a specified cleanliness. Furthermore, the FOUP 102 of the embodiment shown in FIG. 5 has two sidewalls 116 with through holes 118 formed therein, thereby enabling the clean air to flow through inside of the FOUP 102. The FOUP 102 has a plurality of holding shelves formed therein for holding semiconductor wafers W horizontally. The through holes 118 formed in the sidewalls 116 of the FOUP 102 have factors, such as the positions, number, and shapes thereof. Those factors are adapted so as to enable air passing through inside of the FOUP 102 to flow horizontally along the top surface of semiconductor wafers W held by the holding shelves 120. Those factors are also adapted so as to form a laminar boundary layer, a transition layer, and/or turbulent boundary layer on the top surface of the semiconductor wafers W as a protective coating. With this arrangement, by having the clean air flowed at a speed of 100 to 300 mm/sec, airflow on and above the top surface of each of the semiconductor wafers W in the FOUP 102 within the sub-housing 106 exhibits similar behavior to FIG. 4. This results in particles being prevented from adhering to the top surface of semiconductor wafers W.

The sub-housing 106 also has anion supply nozzle 122 disposed thereon for neutralizing static electricity within the airflow to further assist prevention of such adhering.

While description has been made in detail on fundamental novel features of the invention as applied to preferred embodiments thereof, it will be understood that the present invention is not limited to the embodiments described above. Various modifications and changes to such embodiments may be made by those skilled in the art without departing from the spirit of the invention. It is our intention, therefore, to be limited only as indicated by the scope of the claims appended hereto.

For example, the substrate to be handled according to the present invention is not limited to a semiconductor wafer W, but may include a glass substrate for manufacturing a liquid crystal panel.

Furthermore, application of the present invention is not limited to conveyance- or transfer-based systems. Such that, the method and structure for preventing particle-based contamination for a substrate, according to the present invention, is also applicable to facilities and equipment, such as long-term storage facilities for a substrate, and stations for a substrate waiting for next processing in processing chambers.

Moreover, the gas flowing means for producing clean air or clean gas is not limited to the flowing means of circulating type involving fans 40, 110 and filters 42, 114. Also, clean gas may be run downflow toward the top surface of the substrate, as long as a protective coating, such as a laminar boundary layer, a transition layer, and/or a turbulent boundary layer, is formed over an entire area of the top surface of the substrate.

As described above, according to the present invention, particles falling from above the substrate may be prevented from adhering to and depositing on the top surface of the substrate. This is implemented by forming a protective coating, i.e. a laminar boundary layer, a transition layer, and/or turbulent boundary layer on and along the top surface of the substrate. Therefore, the present invention enables to prevent or greatly reduce particle-based contamination of the substrate, thereby providing a remarkable contribution to improvement of characteristics and yield rate of semiconductor devices and liquid crystal panels as the final products from the substrate.

In addition, as described above, the fundamental technical concept of the present invention is applicable to a wide range of fields, including conveyance, storage systems and equipment, as well as substrate processing equipment. Thus, it is possible for the present invention to make an outstanding contribution to the tendency towards finer structures and higher degrees of integration.

It is thought that the present invention and many of its attendant advantages will be understood from the foregoing description and it will be apparent that various changes may be made in the form, construction and arrangement thereof without departing from the spirit and scope of the invention or sacrificing all of its material advantages, the form hereinbefore described being merely a preferred or exemplary embodiment thereof.

What is claimed is:

1. A method for preventing a substrate from being contaminated by particles, said substrate being disposed horizontally in an environment having a specified cleanliness, said method comprising:
the step of flowing clean gas along the top surface of said substrate at a specific relative horizontal speed with respect to said top surface of said substrate, such that a protective coating of said clean gas for protecting said substrate from particles is formed all over an entire area of said top surface of said substrate.

2. A method as recited in claim 1, wherein said protective coating includes a laminar boundary layer, a transition layer, and/or turbulent boundary layer.

3. A structure for preventing a substrate (W) from being contaminated by particles, said structure comprising:
a housing having the inside thereof kept at a specified cleanliness;
a holding means for holding said substrate horizontally inside said housing; and
a gas flowing means for flowing clean gas along the top surface of said substrate at a specific relative speed with respect to said top surface of said substrate, such that a protective coating of said clean gas for protecting said substrate from particles is formed all over an entire area of said top surface of said substrate.

4. A structure as recited in claim 3, wherein said protective coating includes a laminar boundary layer, a transition layer, and/or turbulent boundary layer.

5. A structure as recited in claim 3 or 4, wherein said holding means is adapted to be capable of moving said substrate within said housing.

6. A structure as recited in claim 3 or 4, wherein said gas flowing means includes:
a fan for circulating gas within said housing; and
a filter disposed in a path of said gas circulation, for cleaning said gas to a clean gas having a specified cleanliness.

7. A structure as recited in claim 3 or 4,
wherein said holding means is adapted to be capable of moving said substrate within said housing, and
wherein said gas flowing means includes:
a fan for circulating gas within said housing; and
a filter disposed in a path of said gas circulation, for cleaning said gas to a clean gas having a specified cleanliness.

8. A structure as recited in claim 3 or 4, further comprising:
an ion supply means for supplying the inside of said housing with ion for neutralizing static electricity occurring in particles contained in said clean gas.

9. A structure as recited in claim 5, further comprising:
an ion supply means for supplying the inside of said housing with ion for neutralizing static electricity occurring in particles contained in said clean gas.

10. A structure as recited in claim 6, further comprising:
an ion supply means for supplying the inside of said housing with ion for neutralizing static electricity occurring in particles contained in said clean gas.

11. A structure as recited in claim 7, further comprising:
an ion supply means for supplying the inside of said housing with ion for neutralizing static electricity occurring in particles contained in said clean gas.
